(19) United States
(12) Patent Application Publication
(10) Pub. No.: US 2003/0167428 A1
(43) Pub. Date: Sep. 4, 2003

(54) ROM based BIST memory address translation

(75) Inventor: Spencer Gold, Pepperell, MA (US)

Correspondence Address: LAHIVE & COCKFIELD, 28 STATE STREET, BOSTON, MA, 02109, US

(73) Assignee: SUN MICROSYSTEMS, INC

(21) Appl. No.: 09/835,170

(22) Filed: Apr. 13, 2001

(51) Int. Cl. G11C 29/00

(52) U.S. Cl. 714/720; 714/733

(57) ABSTRACT

A method is provided to perform spatial locality testing on a memory array having a logical address map distinct from its physical address map. The built-in self-test generator performs memory spatial locality tests on the memory array by generating adjacent physical memory row addresses that are then converted to corresponding logical memory row addresses. Once the physical memory row address is converted to its corresponding memory row address the test vector is written to the logical memory row address to perform spatial locality tests on adjacent physical memory row addresses of the memory array.

### TECHNICAL FIELD OF THE INVENTION

The present invention generally relates to memory devices and more particularly, to a method for performing built-in self-test on the memory device.

### BACKGROUND ON THE INVENTION

With the constant improvements in memory fabrication processes, large arrays of memory are easily embedded on a single electronic device. Consequently, external testing of the embedded memory becomes difficult due to the lack of a direct connection between the input pins, output pins, and the embedded memory of the device. As a result, internal testing of embedded memory is often necessary. One conventional technique for internally testing an embedded memory is “built-in self-test” or “BIST”.

With the use of BIST technology, a BIST enhanced device has the capability to test itself for correct functionality upon the occurrence of a particular event. The event may be, for example, each time the device is reset or powered on. Although BIST technology can lower the cost of device test in a production environment and provide significant fault coverage by allowing massively parallel testing, BIST technology also adds to the device's silicon area overhead and can slow access time by adding at least one extra level of logic to the row address decoding logic and the write data logic of the memory itself. Consequently, the implementation of BIST technology is typically reserved for large homogenous structures, such as memory arrays.

BIST technology typically utilizes an address generation engine to provide a series of sequential memory row addresses that are written to and read from by the associated BIST hardware. Since the BIST generation engine provides a series of sequential memory addresses, the memory device is often subjected to neighborhood pattern sensitive tests to detect stuck-at faults, coupling faults and transitional faults between physically adjacent memory cells. The performance of neighborhood pattern sensitive tests using BIST technology is not problematic so long as the logical mapping and the physical mapping of each memory cell in the memory device are consistent.

With the ever increasing advances in solid state memory fabrication, one of the principle causes of memory cell access delay has shifted from the gate delay associated with the memory predecode and decode circuitry to the wire length connecting a memory cell to the decode circuitry. As a result, it may be necessary in certain memory structures to ensure that the load on each row address wire, or row address predecode wire, is evenly distributed across its length. As a consequence, the physical mapping and the logical mapping of a memory cell are not always consistent.

Since BIST technology, and particularly neighborhood pattern sensitive tests, only reveal memory faults when physically neighboring cells are accessed, the BIST address generation engine must be capable of efficiently generating sequences of memory row addresses for memory cells that are physically adjacent. Consequently, utilizing BIST technology to perform neighborhood pattern sensitive tests on a memory array that lacks an consistent logical and physical address mapping is significantly more complex and burdensome.

### SUMMARY OF THE INVENTION

The present invention addresses the above described limitations of performing built-in self-test, when a memory array contains one or more memory cells that have a logical mapping different from their physical mapping. The present invention provides an approach to enable BIST test of a memory array that lacks an consistent logical and physical memory cell address mapping.

In one embodiment of the present invention, a method is practiced where a BIST test vector is generated for a physical row address of the memory array. Based on the physical address generated, the logical address of the memory cells under test is then generated and the test vector is written to the logical address corresponding to memory cells under test. This method can use an additional memory device, such as a ROM device, or it can use a dedicated portion of the embedded memory itself to convert the physical address of memory cells under test to a logical address.

The above-described approach benefits a memory array having a physical address mapping distinct from its logical address mapping. Consequently, an efficient method for generating sequences of logical memory cell address from physically adjacent memory cell addresses is established. In this manner, a memory array having a logical address mapping distinct from its physical address mapping can support the implementation of BIST technology to perform neighborhood pattern sensitive tests.

In accordance with another aspect of the present invention, an integrated circuit is provided. The integrated circuit contains a memory array and a test generator coupled to the memory array to generate a physical address of the memory array and a corresponding test vector. Further, the integrated circuit provides a conversion circuit that converts the physical address of the memory array generated by the test generator into a logical address of the memory array. As a result of the address conversion the test vector generated for the physical memory address is written to the logical memory address to perform neighborhood pattern sensitive tests on physically adjacent cells.

### BRIEF DESCRIPTION OF THE DRAWINGS

An illustrative embodiment of the present invention will be described below relative to the following drawings.

FIG. 1 is a block diagram of an electronic device used in the illustrative embodiment of the present invention.

FIG. 2 illustrates a memory array memory map having a logical address mapping and a physical address mapping that are different.

FIG. 3 is a flow chart illustrating the steps that are performed to allow BIST testing on a memory array lacking consistent logical address and physical address mapping in accordance with the illustrative embodiment of the present invention.

### DETAILED DESCRIPTION

The illustrative embodiment of the present invention provides a method for performing built-in self-test (BIST), on a memory device with a logical row address mapping that is distinct from its physical row address mapping. The illustrative embodiment allows a BIST enhanced device to perform BIST in the logical memory row address space based on test vectors generated in the physical memory row address space.

In the illustrative embodiment, the method for testing an embedded memory is attractive for use in microprocessors where the loads on each of the memory row address wires must be equally distributed across the memory to ensure critical memory access timing. In this manner, the microprocessors can maintain critical memory access timing and still perform BIST on a memory array having a physical row address map distinct from its logical address map.

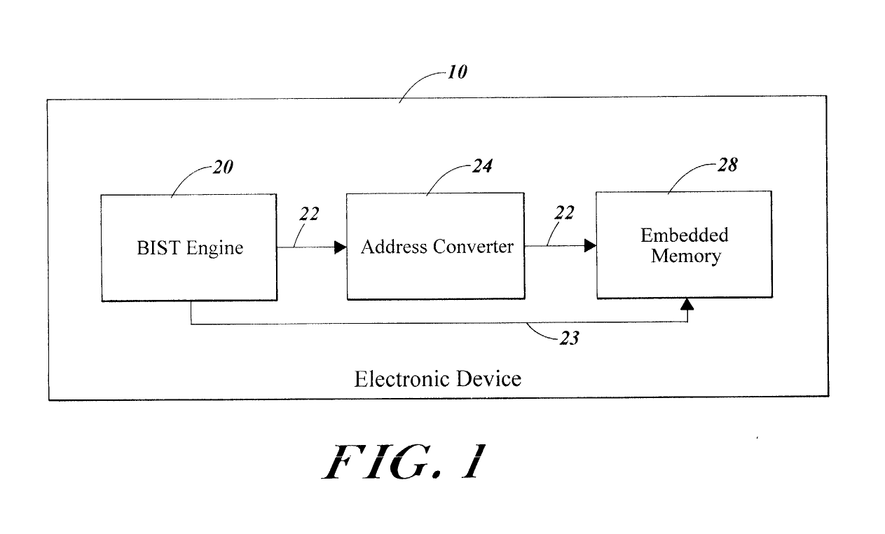

FIG. 1 illustrates an electronic device 10 embodying principles of the present invention. The electronic device 10 includes a BIST engine 20 that generates a test vector for a physical memory row address of the embedded memory 28. A test vector is a vector of binary digits containing both an address and data, wherein the data portion of the vector is written to the memory cells forming a row of the embedded memory to verify functionality of the written to memory cells. The memory address converter 24 converts the physical address generated by the BIST engine 20 to a corresponding logical address in the embedded memory 28. The address converter 24 can be any conventional type of solid state memory device, such as a read only memory (ROM), a random access memory (RAM), an electronically erasable programmable read only memory (EEPROM), or the like. One skilled in the art will recognize that the use of an EEPROM or a RAM as the address converter 24 allows the electronic device 10 to mark out memory cell locations that are determined to be nonfunctional. In this manner, the electronic device 10 avoids replicating memory faults associated with the detected nonfunctional memory cell or cells.

The BIST engine 20 is able to perform a variety of spatial locality tests on the embedded memory 28 in spite of the embedded 28 having a logical memory row address mapping distinct from its physical memory row address mapping. Typically, the BIST engine 20 generates sequential physical addresses of the embedded memory 28 to support neighborhood pattern sensitive tests. In this manner, the BIST engine 20 is able to perform a finite sequence of tests on every cell in the embedded memory array 28 before moving onto the next cell. One skilled in the art will appreciate that the BIST engine 20 can also produce test vectors for physical memory row addresses of the embedded memory 28 to perform march style tests on the embedded memory array 28. Typical march tests detect address faults, stuck-at faults, independent coupling faults, link coupling faults, transition faults, and transition faults linked with coupling faults.

The BIST engine 20 generates test vectors that allows neighborhood pattern sensitive tests, also known as spatial locality tests, on the embedded memory array 28. Those skilled in the art will recognize that the neighborhood pattern sensitive tests exercise every cell in the embedded memory array 28 in relation to its set of neighboring cells. Hence, the BIST engine 20 must generate addresses of memory rows that are physically adjacent. Neighborhood pattern sensitive tests cover classic memory array faults known as active neighborhood pattern sensitive faults, passive neighborhood pattern sensitive faults, and static neighborhood pattern sensitive faults. The neighborhood pattern sensitive tests generated by the BIST engine 20 can detect memory cell stuck-at faults along with memory cell coupling faults between physically adjacent memory cells and memory cell transitional faults between physically adjacent memory cells.

As illustrated in FIG. 1, the address transmission path 22 couples the BIST engine 20 to the address converter 24 and the address converter 24 to the address decoding circuits of the embedded memory array 28 while the data transmission path 23 couples the BIST engine 20 to the data circuits of the embedded memory array 28. Those skilled in the art will recognize that the electronic device of the illustrative embodiment may include more than one address transmission path, such as a write address transmission path coupled to the write port of the embedded memory and a read address transmission path coupled to the read port of the embedded memory.

In operation, the electronic device 10 performs BIST testing at power on, or when a reset signal is received, or when instructed to do so during diagnostics. Those skilled in the art will recognize that the address transmission path 22 can be a bus, a point-to-point transmission path, or the like. The address converter 24 contains the map that converts the physical memory row address generated by the BIST engine 20 to a logical memory row address of the embedded memory array 28. The address converter 24 allows a memory array having a logical address mapping distinct from its physical address mapping, such as the embedded memory array 28, to be BIST enhanced. As such, the BIST engine 20 can generate addresses of physically adjacent memory rows without adding complexity and overhead to the BIST engine 20. Moreover, the address converter 24 may be adapted to support built-in self-repair of the embedded memory array 28.

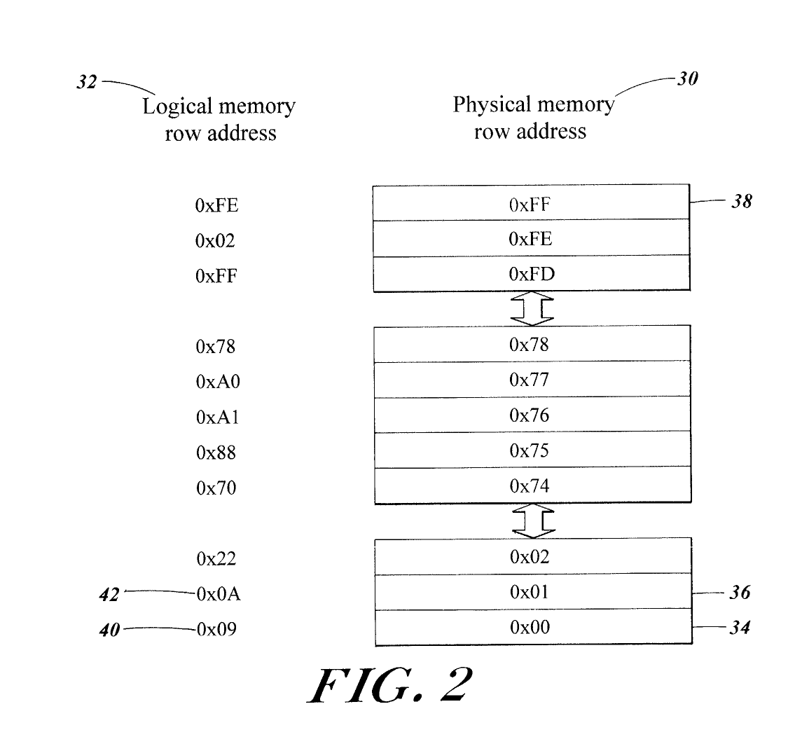

To help illustrate a memory array having a logical memory row address mapping distinct from its physical memory row address mapping, FIG. 2 illustrates an exemplary memory map of the embedded memory 28. FIG. 2 is a simplified view of memory addressing and address space. The memory map of FIG. 2 is based on an 8-bit address architecture. One skilled in the art will recognize that FIG. 2 is not meant to be limiting of the present invention and is merely meant to help illustrate the definition of logical memory row address and physical memory row address.

The BIST engine 20 generates the physical memory address 34 and the adjacent physical memory address 36 to perform neighborhood pattern sensitive tests on these two adjacent memory rows in the physical memory address space 30. The BIST engine 20 passes the physical memory address 34 and the physical memory address 36 to the address converter 24. The address converter 24 maps the physical memory address 34 to the corresponding logical memory address 40, and maps the physical memory address 36 to the corresponding logical memory address 42. The test vectors generated by the BIST engine 20 are then written to the logical memory addresses of the embedded memory array 28 on the data transmission path 23. The BIST engine 20 continues in this fashion by sequentially generating physical memory row addresses of the embedded memory array 28 until generating the final physical memory row 38.

The BIST engine 20 reads from the embedded memory array 28 by passing the physical memory address 36 to the address converter 24. The address converter 24 maps the physical memory address 36 to the corresponding logical memory address 42 which is passed to the embedded memory 28 over the address transmission path 22. The BIST engine 20 reads the data in the logical memory address 42 using the data transmission path 23. In this fashion, the BIST engine 20 can evaluate the functionality of physically adjacent memory cells in the embedded memory array 28. Those skilled in the art will recognize that the electronic device of the illustrative embodiment can include more than one data bus, such as a read data bus and a write data bus.

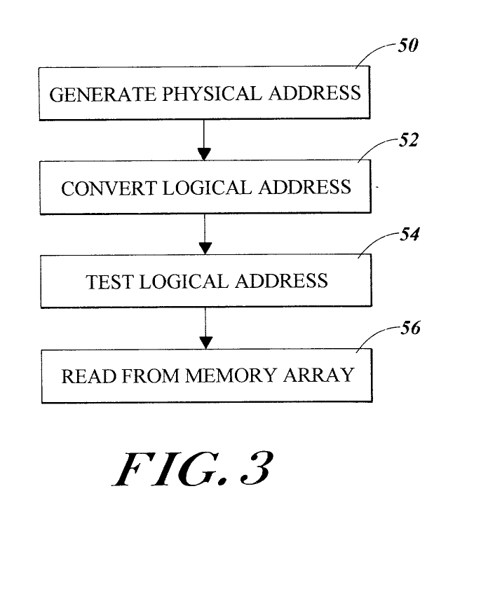

With reference to FIG. 2 and FIG. 3, upon initiation of BIST, the BIST engine 20 initially generates the first physical memory row address 34 and its corresponding test vector (Step 50 in FIG. 3) and asserts the physical memory row address onto the address transmission path 22 to the address converter 24 and asserts the corresponding test vector onto the data transmission path 23. The address converter 24 reads the physical address provided by the address transmission path 22 and converts the physical memory row address asserted by the BIST engine 20 to the corresponding logical memory row address 40 (Step 52 in FIG. 3). In this manner, the address converter 24 reads the physical memory row address generated by the BIST engine 20 and writes the logical memory row address 40 in the logical memory address space 32. As a result, neighborhood pattern sensitive tests are performed on the first physical memory row address 34 and the second physical memory row address 36 (Step 54 in FIG. 3). To determine the functionality of the physical memory row address under test, the electronic device 10 or the BIST engine 10, reads from the adjacent physical memory cell to detect stuck-at faults, coupling faults between physically adjacent memory cells, and transitional faults between the adjacent memory cells (Step 56 in FIG. 3).

While the present invention has been described with reference to an illustrative embodiment thereof, those skilled in the art will appreciate that various changes in form and detail may be made without departing from the intended scope of the present invention as defined in the appending claims. For example, an offset may be added to the physical memory address generated by the BIST engine to initiate BIST at a targeted memory location.

1. An integrated circuit comprising:
a memory array;
a test generator coupled to the memory array to generate a physical address in the memory array and to generate a test vector for the physical address wherein said test vector allows detection of a non-complaint memory cell of said memory array; and
a conversion circuit to convert the physical address in the memory array to a logical address in the memory array to allow said test vector to be written to said logical address of the memory array.

2. The integrated circuit of claim 1, wherein the conversion circuit comprises a Read Only Memory (ROM).

3. The integrated circuit of claim 1, wherein the conversion circuit comprises a Random Access Memory (RAM).

4. The integrated circuit of claim 1, wherein the conversion circuit comprises an Electrically Erasable Programmable Read Only Memory (EEPROM).

5. The integrated circuit of claim 1, wherein the test vector is capable of detecting spacial locality faults within the memory array.

6. The integrated circuit of claim 1, wherein the test vector is capable of detecting coupling transitional faults between physically adjacent memory cells.

7. A method for testing an embedded memory having memory cells, the method, comprising the steps of:
providing a test vector for a first address in the embedded memory;
determining a second address in the embedded memory based on the first address; and
writing the test vector to the second address to detect non-functional memory cells represented by the second address.

8. The method of claim 7, further comprising the step of reading the second memory address written to detect non-functioned memory cells.

9. The method of claim 7, wherein the first address is a physical memory address of the embedded memory.

10. The method of claim 9, wherein the second address is a logical memory address of the embedded memory.

11. The method of claim 7, wherein a Read Only Memory (ROM) device holds the second address of the embedded memory based on the first address generated for the embedded memory.

12. The method of claim 7, wherein a Random Access Memory (RAM) device holds the second address of the embedded memory based on the first address generated for the embedded memory.

13. The method of claim 7, wherein said testing of the embedded memory comprises neighborhood pattern sensitive testing.

14. The method of claim 7, wherein said testing of the embedded memory comprises march pattern testing.

15. In a memory array having a physical mapping scheme distinct by at least one bit from its logical mapping scheme, a method for performing built-in self-test on the memory array, the method comprising the steps of:
generating a physical row address for the memory array;
generating a logical row address for the memory array based on the physical row address; and
performing the built-in self-test on the memory array based on the generated logical row address.

16. The method of claim 15 further comprising the step of, performing the built-in self-test on a selected cell of the memory array based on the generated logical row address.

17. The method of claim 15 further comprising the step of, performing the built-in self-test on a selected memory block of the memory array based on the generated logical row address.

18. The method of claim 15, wherein an integrated circuit generates the logical row address for the memory array based on the physical row address for the array.

19. The method of claim 18, wherein the integrated circuit is a Read Only Memory (ROM) device.

20. The method of claim 18, wherein the integrated circuit is a Random Access Memory (RAM) device.

21. The method of claim 18, wherein the integrated circuit is an Electrically Erasable Programmable Read Only Memory (EEPROM).

22. The method of claim 15, wherein the built-in self-test comprises Neighborhood Pattern Sensitive Tests.

23. The method of claim 15, wherein the built-in self-test comprises March Tests.

24. A semiconductor device comprising:
a test circuit; and
a conversion circuit, coupled to said test circuit wherein the test vector circuit provides a physical memory row address for a selected group of memory cells under test to the conversion circuit for conversion of the provided physical memory address to a logical memory address for the selected group of memory cells under test.

25. The semiconductor device of claim 24, wherein the conversion circuit comprises a Read Only Memory (ROM).

26. The semiconductor device of claim 24, wherein the conversion circuit comprises a Random Access Memory (RAM).

27. The semiconductor device of claim 24, wherein the conversion circuit comprises an Electrically Erasable Programmable Read Only Memory (EEPROM).

28. The semiconductor device of claim 24, wherein the test circuit provides a test vector capable of detecting spacial locality faults within the selected group of memory cells under test,

29. The semiconductor device of claim 24, wherein the test circuit provides a test vector capable of detecting coupling transitional faults between physically adjacent memory cells within the selected group of memory cells under test.
